(19) United States
(12) Patent Application Publication
(10) Pub. No.: US 2009/0047433 A1
(43) Pub. Date: Feb. 19, 2009

(54) SUBSTRATE PROCESSING APPARATUS AND METHOD

(76) Inventors: Chun-Sik KIM, Seongam-si (KR); Gyeong-Hoon Kim, Anyang-si (KR)

Correspondence Address: KED & ASSOCIATES, LLP, P.O. Box 221200, Chantilly, VA, 20153-1200, US

(21) Appl. No.: 12/146,730

(22) Filed: Jun. 26, 2008

(30) Foreign Application Priority Data
Aug. 13, 2007 (KR) 10-2007-0081382
Sep. 20, 2007 (KR) 10-2007-0096099

(51) Int. Cl. B05D 3/00; C23C 14/00

(52) U.S. Cl. 427/294; 118/50

(57) ABSTRACT

A substrate processing apparatus includes a first chamber, a second chamber provided adjacent the first chamber to form a process space therebetween, a support unit supporting the second chamber with a gap between the first and second chambers, and a vacuum unit to place the process space in a vacuum state, the process spaced sealed in the vacuum state.

### BACKGROUND

1. Field

One or more embodiments described herein relate to processing substrates including semiconductor substrates.

2. Background

Flat panel displays and semiconductor devices are manufactured using a variety of processes. The manufacturing processes for both devices are very similar and are performed in a process chamber maintained in a vacuum or atmospheric state.

The process chamber includes an upper chamber located over a lower chamber, and includes a process space that is sealed from the outside during the process. A support member and a shower head are provided in the process space. During the process, a substrate is placed on a support member in the process space and a plasma gas is supplied to the substrate through a shower head. In the case where the process uses plasma, plasma is generated from the process gas by an additional plasma generating member.

For maintenance purposes, the inside of the process chamber should be repaired or checked after a certain number of processes have been performed. In order to allow for repairs, one type of process chamber includes an apparatus for opening/closing the upper chamber. The upper chamber is opened by a crane provided over the upper chamber or by using an additional opening/closing apparatus provided at a side part of the process chamber.

### BRIEF DESCRIPTION OF THE DRAWINGS

FIG. 1 is a drawing showing a manufacturing instrument that includes a substrate processing apparatus.

FIG. 2 is a diagram showing one embodiment of a substrate processing apparatus.

FIG. 3 is a diagram showing another view of the substrate processing apparatus of FIG. 2.

FIG. 4 is a diagram showing an operation for closing a process space of the substrate processing apparatus of FIG. 2 using a vacuum unit.

FIGS. 5a, 5b, and 6 are diagrams showing operation of horizontal moving and rotation members of the substrate processing apparatus of FIG. 3.

FIG. 7 is a diagram showing another embodiment of a substrate processing apparatus.

FIG. 8 is a diagram showing an operation for closing a process space of the substrate processing apparatus of FIG. 7 using a vacuum unit.

FIG. 9 is a diagram showing an operation for opening the process space of the substrate processing apparatus of FIG. 7.

FIG. 10 is a diagram showing another embodiment of a substrate processing apparatus.

FIG. 11 is a diagram showing another view of the substrate processing apparatus of FIG. 10.

FIG. 12 is a diagram showing an operation for closing a process space of the substrate processing apparatus of FIG. 10 using a vacuum unit.

FIGS. 13a, 13b, and 14 are diagrams showing operation of horizontal moving and rotation members of FIG. 11.

### DETAILED DESCRIPTION

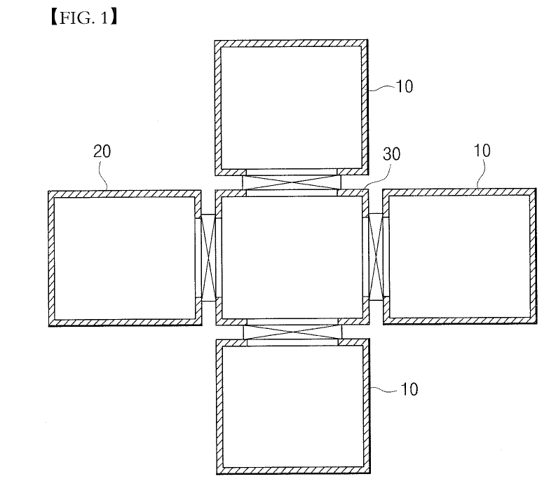

FIG. 1 shows a manufacturing instrument that includes one or more substrate processing apparatuses 10, a load lock chamber 20, and a transfer chamber 30. The load lock chamber 20 receives an unprocessed substrate or discharges a processed substrate. The transfer chamber 30 may include a robot for transferring a substrate to be processed to or from chambers 10. For example, the transfer chamber transfers a substrate from the load lock chamber to one of the substrate processing apparatuses, or transfers a processed substrate from one of apparatuses 10 to the load lock chamber.

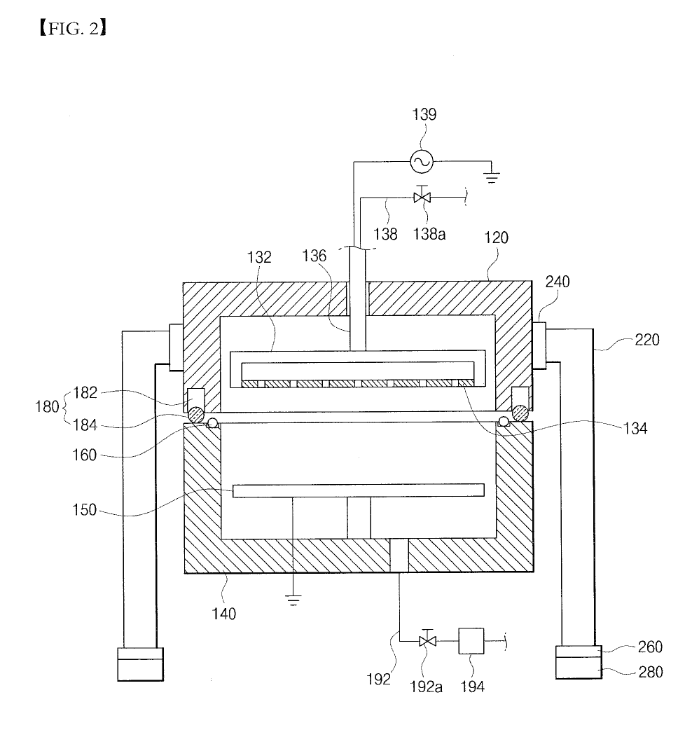

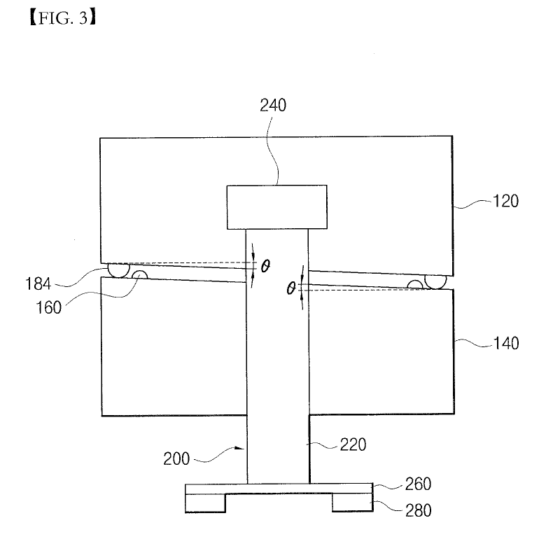

FIG. 2 shows one embodiment of a substrate processing apparatus 10, and FIG. 3 shows another view of this substrate processing apparatus.

The substrate processing apparatus includes upper and lower chambers 120 and 140. The upper chamber is placed on the lower chamber during a process to be performed. However, the upper chamber may be separated from the lower chamber when the upper and lower chambers are to be repaired. A process space is formed inside the upper and lower chambers. Processes are performed on the substrate in this space. The process space may be kept in a vacuum state during this time.

A support plate 150 and a shower head are provided in the process space. The substrate may be placed on the support plate and the shower head may be provided over the support plate to supply process gas. The support plate is preferably grounded and plasma is generated over the support plate with an upper electrode 132.

The shower head includes upper electrode 132, a spray plate 134, and a vertical shaft 136. A lower end of the vertical shaft is connected to the upper electrode, and an upper end of the vertical shaft is connected to a supply line 138 and an RF generator 139. The supply line 138 is opened or closed by a valve 138a and supplies source gas to space between the upper electrode and spray plate. The RF generator operates, for example, at 13.56 MHz, and is connected to the upper electrode. During the process, the source gas is supplied above support plate 150 through spray plate 134. Then, plasma is generated by an electric field formed between the upper electrode and support plate. The plasma is then used in the process.

The upper chamber 120 is supported by a support unit 200. The support unit includes a support shaft 220, a rotation member 240, an upper plate 260, and a horizontal moving member 280. The support unit supports the upper chamber on the lower chamber 140 so as to form a gap between them. The rotation member is fixed to both sides of the upper chamber. One end of the support shaft is connected to the rotation member, and the other end is fixed to the upper plate 260. The horizontal moving member is provided at a lower end of the upper plate, and moves the upper chamber 120 horizontally.

A sealing member 160 is provided between the upper and lower chambers. More specifically, the sealing member is provided on an upper surface of the lower chamber 140 and a gap formed between the upper and lower chambers. As shown in FIG. 2, the sealing member is spaced from the lower surface of the upper chamber, and is pressed to seal the process space from the outside when vacuum state is formed in the process space.

Referring again to FIG. 2, a plunger 180 is inserted into the lower surface of the upper chamber 120. The plunger includes a housing 182 inserted into the upper chamber and a ball 184 inserted into the housing. The ball may be inserted into the housing or may project from the housing. The ball can be driven by various methods including supplying air into the housing or removing air from the housing in order to press or move the ball. As shown in FIG. 2, in the state that the process space is not closed, the ball may project out of the housing 182 and contact the upper surface of the lower chamber 140 to support the upper chamber.

An exhaust line 192 is connected to a lower part of the lower chamber 140, and a pump 194 is provided on the exhaust line to keep the process space in a vacuum state by exhausting gas in the process space through the exhaust line. The exhaust line is opened or closed by a valve 192a.

As shown in FIG. 3, the lower surface of the upper chamber 120 and the upper surface of the lower chamber 140 may be inclined by a predetermined angle (θ) along the moving direction of the upper chamber. The inclination direction is inclined downward from the front end to the rear end of the upper chamber 120 moving toward the lower chamber 140.

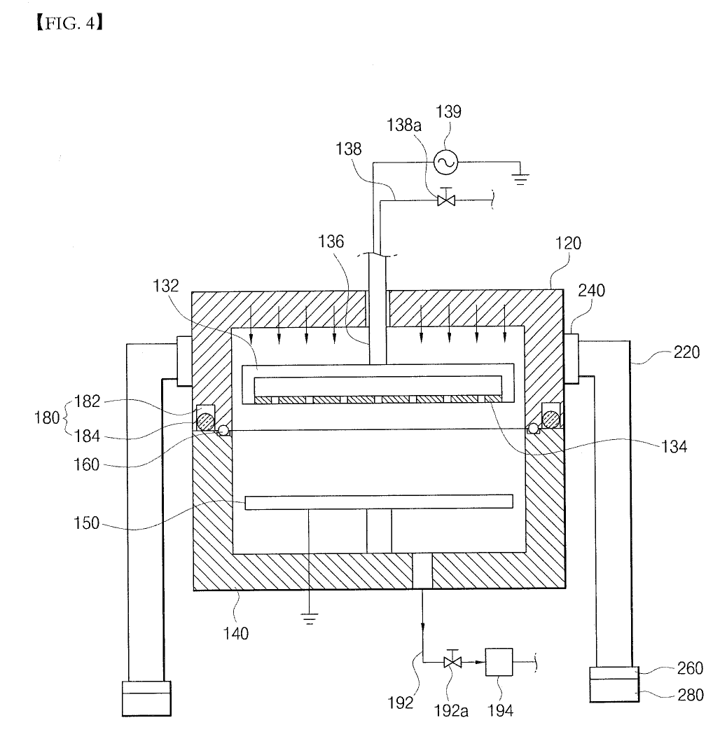

FIG. 4 shows an operation for closing a process space of the substrate processing apparatus of FIG. 2 using a vacuum unit. A corresponding method of closing the process space of the substrate processing apparatus will also be explained with reference to FIG. 4.

First, when gas is exhausted out of the process space through exhaust line 192, in a state where ball 184 has been inserted into housing 182, internal pressure of the process space is decreased lower than external pressure. As a result, the upper and lower chambers 120 and 140 are pressurized based on a difference between the inside and outside pressures.

The pressure applied to lower chamber 140 is opposite to the direction of gravity. The pressure applied to upper chamber 120 is the same as the direction of gravity. Accordingly, the pressure applied to the lower chamber can be canceled by gravity. However, the pressure applied to upper chamber is added to gravity. Thus, the upper chamber moves downward and the gap between the upper and lower chambers is closed by coupling of the upper and lower chambers or by contact between upper chamber 120 and sealing member 160.

When the vacuum is vented, there is no pressure difference inside and outside the process space. Accordingly, the upper chamber can be restored to its original position. Then, the gap between the upper and lower chambers is opened. Such an operation can be performed through elastic deformation of the support shaft 220 or upper chamber 120. The support shaft may be made of an elastic material to support movement of the upper chamber. (Elastic deformation is opposite to plastic deformation. In elastic deformation, the deflection and strain of a specimen are determined based on a magnitude of an applied load, e.g., a constant load. When the load is removed, the specimen is restored to the original shape without any permanent set.)

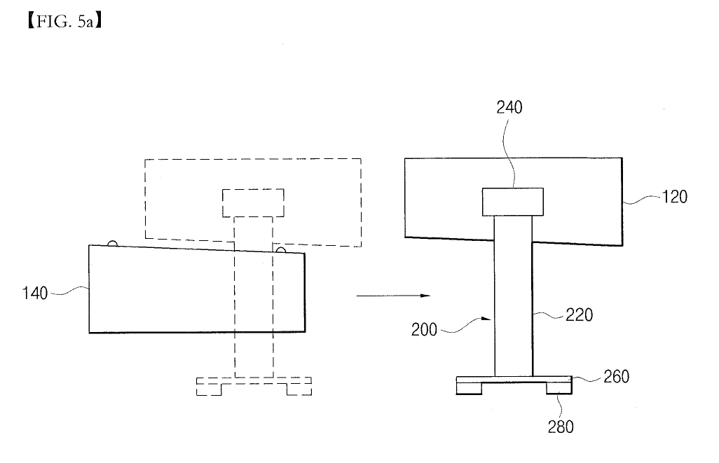

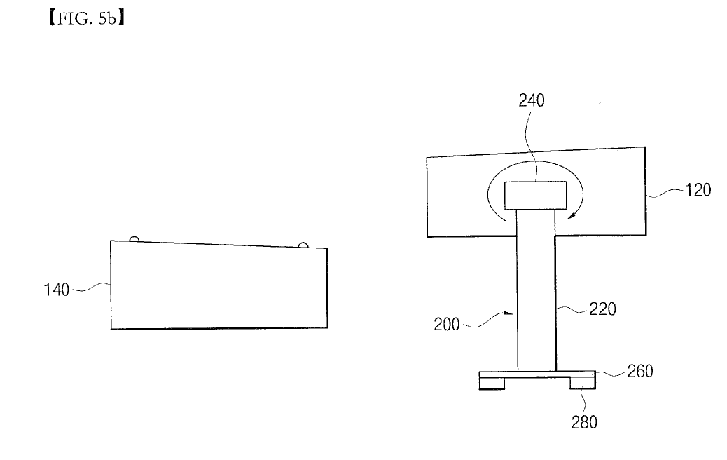

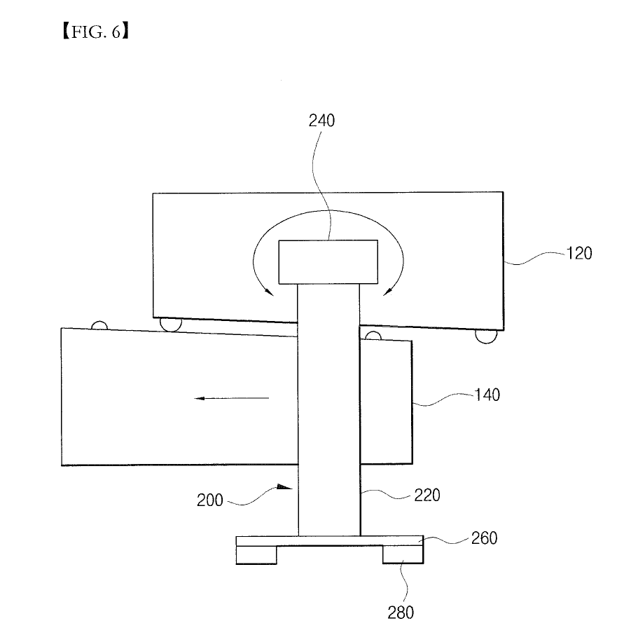

FIGS. 5a, 5b, and 6 show an operation of a horizontal moving member 280 and a rotation member 240 of FIG. 3. The horizontal moving member is provided on a bottom surface of upper plate 260, and moves the upper plate and support shaft 220, for example, along an additional guide rail. As shown in FIG. 5a, the horizontal moving member moves the upper chamber 120 horizontally to the right using the support shaft. The lower surface of the upper chamber and the upper surface of the lower chamber are inclined. Accordingly, the upper chamber can be moved without collision between the upper and lower surfaces. After upper chamber 120 moves to a desired position, rotation member 240 makes the lower surface of the upper chamber 120 face upward as a result of rotation of the upper chamber.

When the upper chamber is moved over the lower chamber, horizontal moving member 280 moves the upper chamber horizontally to the left as shown in FIG. 6. At this time, the upper and lower chambers may collide when the front or rear of the upper chamber sags downward. Accordingly, the position of the upper chamber is aligned by projecting ball 184 from housing 182 and moving the ball along the upper surface of the lower chamber. In other words, while the ball moves along the upper surface of the lower chamber, upper chamber 120 rotates clockwise or counterclockwise, thereby preventing the front or rear of the upper chamber from sagging.

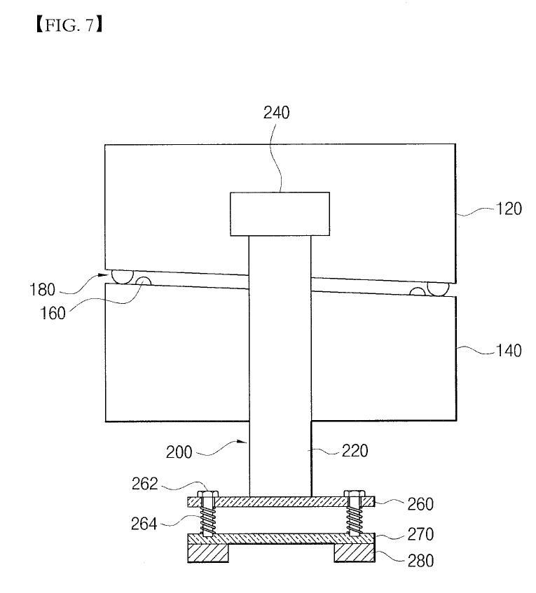

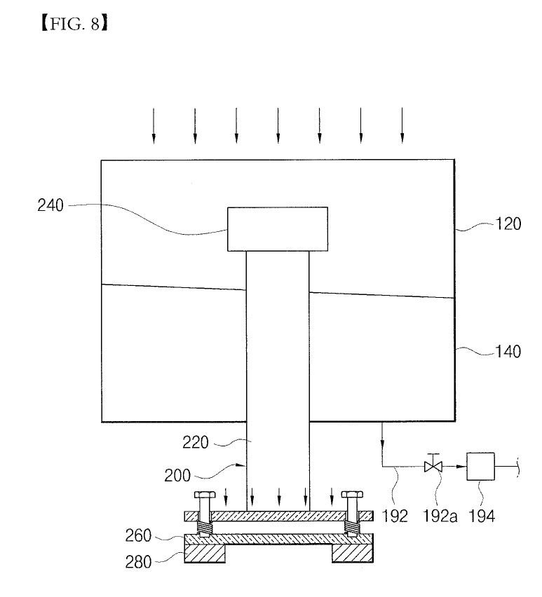

FIG. 7 shows another embodiment of substrate processing apparatus 10, and FIG. 8 shows an operation for closing the process space of this apparatus using exhaust line 192.

As shown, support unit 200 includes a lower plate 270, a connection member 262, and an elastic member 264. The lower plate is provided below and in parallel with upper plate 260. The connection member connects the upper plate to the lower plate, and restricts the upper plate to allow the upper plate to move relative to the lower plate. Elastic member 264 is provided on the connection member. In the previous embodiment, the process space is closed by elastic deformation of the support shaft or upper chamber. However, in this embodiment, the process space is closed by deformation of the additional elastic member 264.

When the gas is exhausted from the process space through exhaust line 192, upper chamber 120 is moved downward. Accordingly, upper plate 260 moves toward lower plate 270 (FIG. 8) and elastic member 264 is compressed. Thus, the gap between the upper and lower chambers is closed by coupling of the upper and lower chambers or by contact between the upper chamber and sealing member 160.

When the vacuum is vented, the elastic member is restored to an original state and simultaneously the upper chamber and upper plate are restored to their original positions, and thus the gap between the upper and lower chambers is opened.

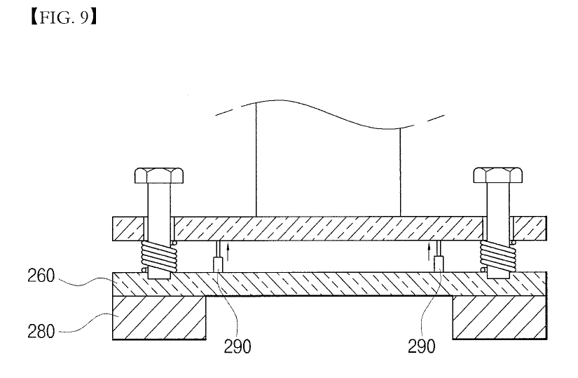

FIG. 9 shows an operation for opening the process space of the substrate processing apparatus of FIG. 7. In the previous embodiment, compressed elastic member 264 is restored and simultaneously upper chamber 120 and upper plate 260 are restored to their original positions. However, in this embodiment, the upper chamber and upper plate are restored to their original positions by an elastic force of elastic member 264 and a driving force of a cylinder 290. In other words, the elastic force of the elastic member and driving force of the cylinder, caused by venting the vacuum, are applied to upper chamber 120 and upper plate 260. Accordingly, the upper chamber and upper plate are restored to their original positions, and thus the gap between the upper and lower chambers is opened.

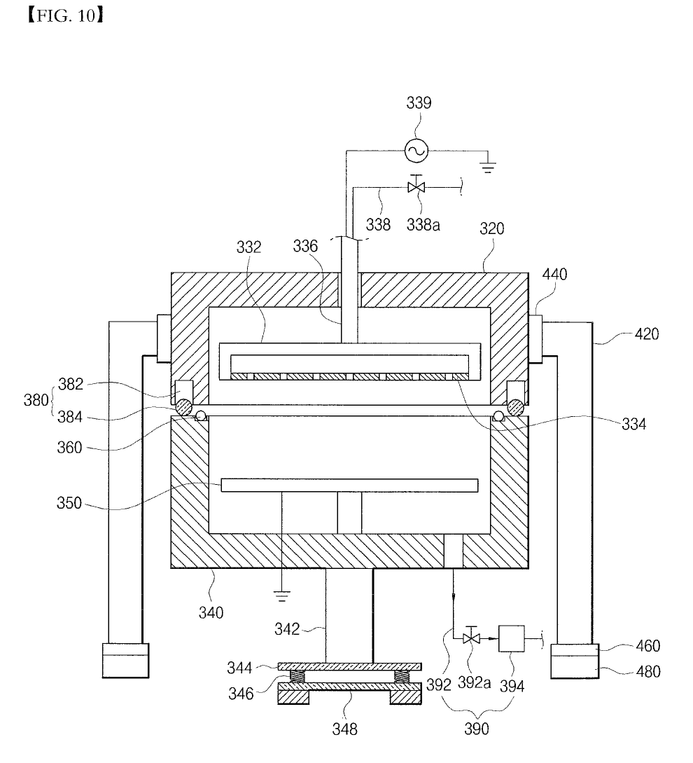

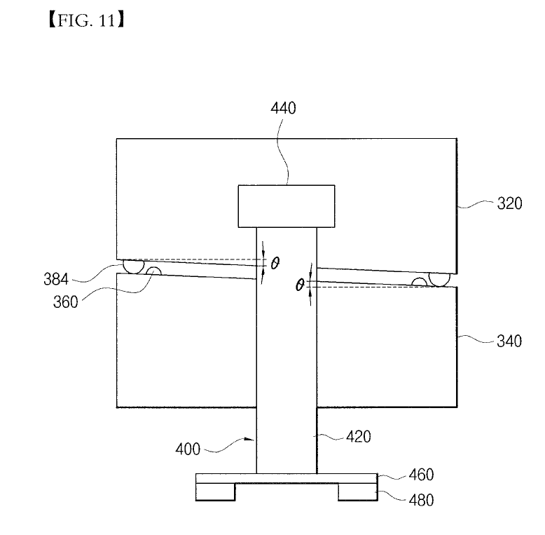

FIG. 10 shows another embodiment of a substrate processing apparatus and FIG. 11 shows another view of this apparatus. This embodiment of the substrate processing apparatus includes upper and lower chambers 320 and 340. The upper chamber is placed on the lower chamber during process. However, the upper chamber may be separated from the lower chamber when the inside of the upper and lower chambers are repaired. A process space is formed inside the upper and lower chambers. Processes are performed on the substrate in the process space, while the process space is kept in a vacuum state.

A support plate 350 and a shower head are provided in the process space. The substrate is placed on the support plate and the shower head is provided over the support plate 350 to supply process gas. The support plate is grounded and generates plasma over the support plate with an upper electrode 332. The shower head includes an upper electrode 332, a spray plate 334, and a vertical shaft 336. A lower end of the vertical shaft is connected to the upper electrode, and an upper end of the vertical shaft is connected to a supply line 338 and an RF generator 339. The supply line 338 is opened or closed by a valve 338a to supply source gas to space between the upper electrode and spray plate. The RF generator operates, for example, at 13.56 MHz, and is connected to upper electrode 332. During processing, the source gas is supplied above support plate 350 through the spray plate 334. Then, plasma is generated by an electric field formed between the upper electrode and support plate. The plasma is then used in the process.

The upper chamber 320 is supported by a first support unit 400, which includes a first support shaft 420, a rotation member 440, a first upper plate 460, and a horizontal moving member 480. The first support unit supports upper chamber 320 on lower chamber 340 so as to form a gap therebetween. The rotation member is fixed to both sides of the upper chamber. One end of the first support shaft is connected to the rotation member, and the other end is fixed to first upper plate 460. The horizontal moving member is provided at a lower end of the first upper plate, and moves upper chamber 320 horizontally.

The lower chamber 340 is supported by a second support unit, which includes a second support shaft 342, a second upper plate 344, an elastic member 346, and a lower plate 348. The second support unit supports lower chamber 340 under upper chamber 320 so as to form a gap between them. One end of the second support shaft is connected to the second upper plate, and the other end is fixed to the second upper plate. The lower plate is provided at a lower end of and in parallel with the second upper plate. The elastic member 346 is provided between the second upper plate 344 and lower plate 348.

A sealing member 360 is provided between upper and lower chambers 320 and 340. More specifically, the sealing member is provided on an upper surface of the lower chamber and a gap formed between the upper and lower chambers. As shown in FIG. 10, the sealing member is spaced from the lower surface of the upper chamber. However, the sealing member is pressed to the lower surface of the upper chamber to seal the process space from the outside when vacuum state is formed in the process space.

Referring to FIG. 10, a plunger 380 is inserted into the lower surface of the upper chamber. The plunger includes a housing 382 inserted into the upper chamber and a ball 384 inserted into housing 382. The ball may be inserted into or project from the housing. The ball can be driven by various methods, e.g., the ball may be pressed by air supplied into the housing or by removing air from the housing. As shown in FIG. 10, in the state that the process space is not closed, the ball projects out of housing 382 and contacts the upper surface of lower chamber 340, thereby forming a gap of a predetermined size between the upper and lower chambers.

An exhaust line 392 is connected to a lower part of lower chamber 340, and a pump 394 is provided on exhaust line 392. The pump keeps the process space in a vacuum state by exhausting gas in the process space through the exhaust line. The exhaust line is opened or closed by a valve 392a.

On the other hand, as shown in FIG. 11, the lower surface of the upper chamber and the upper surface of the lower chamber are inclined by a predetermined angle (θ) along the moving direction of the upper chamber. The inclination direction is inclined downward from the front end to the rear end of upper chamber 320 moving toward lower chamber 340. In other embodiments, the angle may be different.

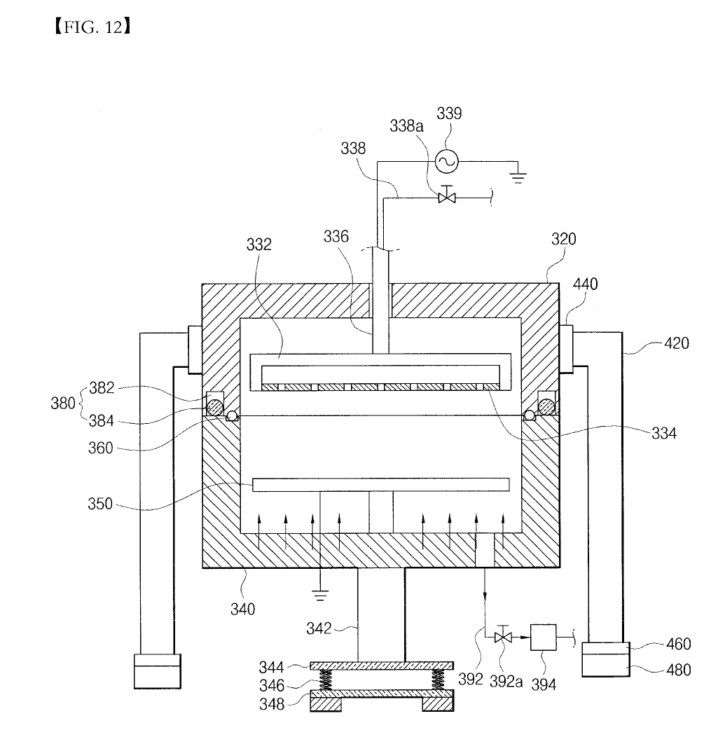

FIG. 12 shows an operation for closing the process space of substrate processing apparatus 30 using exhaust line 392. An embodiment of a method of closing the process space of a substrate processing apparatus will also be explained below with reference to FIG. 12.

First, when gas is exhausted out of the process space through exhaust line 392 in the state that ball 384 has been inserted into housing 382, internal pressure of the process space is decreased lower than external pressure. Accordingly, upper and lower chambers 320 and 340 are pressurized by a difference between inside and outside pressures.

At this time, the upper chamber is restricted by first support shaft 420 and thus cannot move in a vertical direction. On the other hand, lower chamber 340 can freely move in the vertical direction by elastic member 346 and thus the lower chamber moves upward by pressure. Thus, a gap between the upper and lower chambers is closed by coupling of the upper and lower chambers or as a result of contact between upper chamber 320 and sealing member 360.

When the vacuum is vented, there is no pressure difference inside and outside the process space. Accordingly, the upper chamber can be restored to its original position (moved downward) and the gap between the upper and lower chambers is opened. Such an operation can be performed through elastic deformation of elastic member 346. (As previously explained, elastic deformation is opposite to plastic deformation. In elastic deformation, deflection and strain of a specimen are determined according to a magnitude of a constant load. When the load is removed, the specimen is restored to the original shape without any permanent set.)

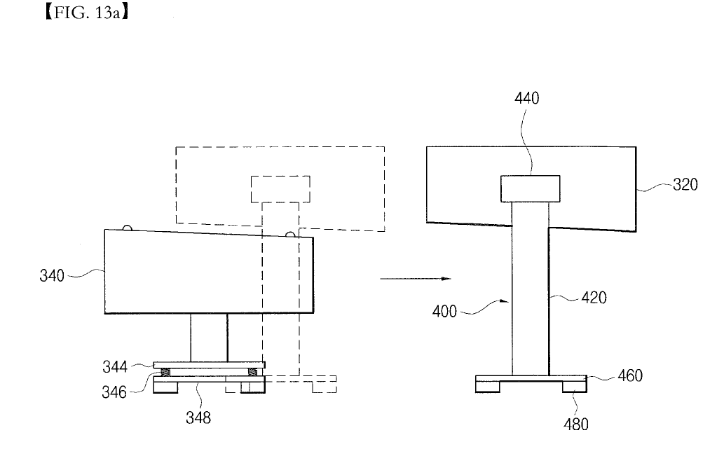

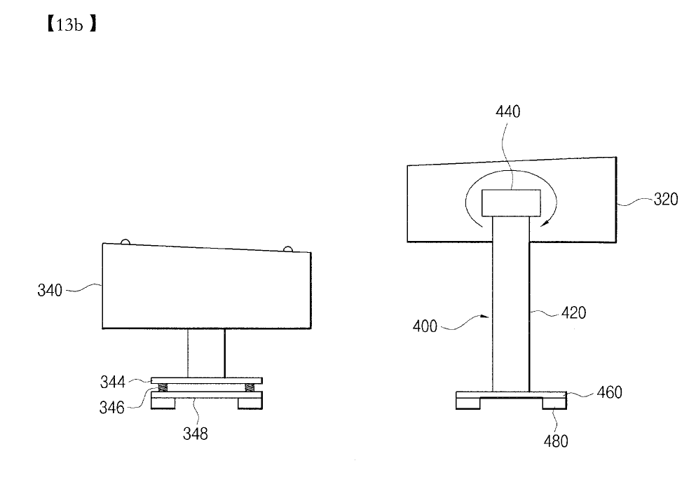

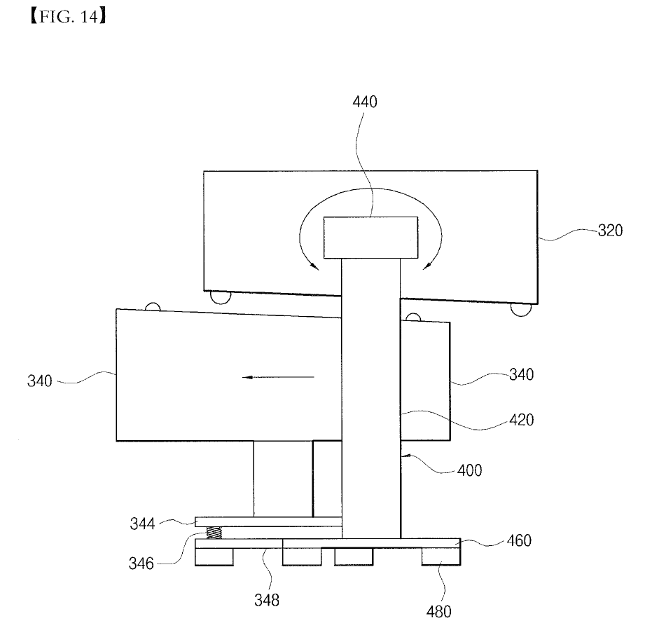

FIGS. 13a, 13b, and 14 show operation of horizontal moving member 480 and rotation member 440 of FIG. 11. The horizontal moving member is provided on a bottom surface of the first upper plate 460. The horizontal moving member may move the first upper plate and first support shaft 420, for example, along an additional guide tail.

As shown in FIG. 13a, the horizontal moving member moves the upper chamber 320 horizontally to the right using first support shaft 420. At this time, the lower surface of the upper chamber and the upper surface of the lower chamber are inclined. Accordingly, the upper chamber can be moved without collision between the upper and lower surfaces. After the upper chamber moves to a desired position, rotation member 440 makes the lower surface of the upper chamber face upward as a result of rotation of the upper chamber.

When the upper chamber is moved over the lower chamber, the horizontal moving member 480 moves the upper chamber horizontally to the left as shown in FIG. 14. At this time, the upper and lower chambers may collide with each other when the front or rear of the upper chamber 320 is sags downward. Accordingly, the position of the upper chamber is aligned by projecting ball 384 from housing 382 and moving the ball along the upper surface of the lower chamber. In other words, while the ball moves along the upper surface of the lower chamber, the upper chamber 320 rotates clockwise or counterclockwise, thereby preventing the front or rear of the upper chamber 320 from sagging.

Thus, the embodiments described herein therefore provide a substrate processing apparatus that uses a simple opening/closing method and at the same time may also be used to open and close a process space. These embodiments also provide a substrate processing apparatus that can minimize an occupied area for installation, and a method which at the same time can open and close a process space.

According to one embodiment, a substrate processing apparatus includes a lower chamber; an upper chamber provided over the lower chamber to form a process space therein with the lower chamber during process, where the process space is sealed from the outside; a support unit supporting the upper chamber so as to form a gap between the upper and lower chambers; and a vacuum unit sealing the process space by keeping the process space in a vacuum state.

The substrate processing apparatus may further include a sealing member provided in the gap formed between the upper and lower chambers to close the gap during the vacuum state. The support unit may include a support shaft made of elastic material that supports the upper chamber by one end connected to the upper chamber and an upper plate connected to the other end of the support shaft.

In addition, the support unit may include a lower plate provided below the upper plate, and a connection member that connects the upper and lower plates to each other and restricts the upper plate so as to allow the upper plate to move relatively to the lower plate. In addition, the support unit may further include an elastic member provided between the upper and lower plates.

The support unit may further include a plunger inserted into a lower surface of the upper chamber adjacent to an upper surface of the lower chamber, where the plunger includes a support body supporting the upper chamber in a state of being projected from the lower surface of the upper chamber.

The support unit may further include a horizontal moving member that moves the upper chamber horizontally relative to the lower chamber along one direction, where the lower surface of the upper chamber and the upper surface of the lower chamber face each other and are inclined in parallel with each other along the one direction, and the inclination direction may be inclined downward from the front end to the rear end of the upper chamber moving toward the lower chamber.

The support unit may further include a plunger inserted into the lower surface of the upper chamber adjacent to the upper surface of the lower chamber, where the plunger includes a support body aligning position of the upper chamber moving toward the lower chamber in a state of being projected from the lower surface of the upper chamber. The support unit may further include a rotation member to make the lower surface of the upper chamber face upward by rotating the upper chamber.

According to another embodiment, a method of opening/closing a process space in a substrate processing apparatus having upper and lower chambers includes providing the upper chamber over the lower chamber so as to form a gap therebetween, and closing the process space after the process space formed inside the upper and lower chambers is kept in a vacuum state. The process space may be closed during the vacuum state by using a sealing member provided in the gap formed between the upper and lower chambers. In addition, the process space may be opened by venting the vacuum.

The support unit may include a support shaft made of elastic material that supports the upper chamber by one end connected to the upper chamber. The support unit may further include an upper plate connected to the other end of the support shaft, a lower plate provided below the upper plate and an elastic member provided between the upper and lower plates.

The substrate processing apparatus may further include a sealing member provided in the gap formed between the upper and lower chambers to close the gap during the vacuum state.

The substrate processing apparatus may further include a plunger inserted into a lower surface of the upper chamber adjacent to an upper surface of the lower chamber, where the plunger includes a support body supporting the upper chamber in a state of being projected from the lower surface of the upper chamber.

The support unit may further include a horizontal moving member that moves the upper chamber horizontally relative to the lower chamber along one direction, where the lower surface of the upper chamber and the upper surface of the lower chamber face each other and are inclined in parallel with each other along the one direction, and the inclination direction may be inclined downward from the front end to the rear end of the upper chamber moving toward the lower chamber.

The substrate processing apparatus may further include a plunger inserted into the lower surface of the upper chamber adjacent to the upper surface of the lower chamber, where the plunger includes a support body aligning position of the upper chamber moving toward the lower chamber in a state of being projected from the lower surface of the upper chamber. The support unit may further include a rotation member to make the lower surface of the upper chamber face upward by rotating the upper chamber.

The embodiments described herein may achieve one or more of the following effects. The occupied installation are can be minimized by opening/closing the process space using the simple opening/closing method.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments of the present invention have been described with reference to a number of illustrative embodiments thereof, it should be understood that numerous other modifications and embodiments can be devised by those skilled in the art that will fall within the spirit and scope of the principles of this invention. More particularly, reasonable variations and modifications are possible in the component parts and/or arrangements of the subject combination arrangement within the scope of the foregoing disclosure, the drawings and the appended claims without departing from the spirit of the invention. In addition to variations and modifications in the component parts and/or arrangements, alternative uses will also be apparent to those skilled in the art.

What is claimed is:

1. A substrate processing apparatus, comprising:
a first chamber;
a second chamber provided adjacent the first chamber to form a process space therebetween;
a support unit supporting the second chamber with a gap between the first and second chambers; and
a vacuum unit to place the process space in a vacuum state, the process spaced sealed in the vacuum state.

2. The apparatus of claim 1, further comprising:
a sealing member provided in the gap between the first and second chambers to close the gap during the vacuum state.

3. The apparatus of claim 1, wherein the support unit comprises:
a support shaft, having a first end coupled to the second chamber, to support the second chamber; and
a first plate connected to a second end of the support shaft, wherein the support shaft is made of an elastic material.

4. The apparatus of claim 3, wherein the support unit further comprises:
a second plate adjacent the first plate; and
a connection member that connects the first and second plates to each other and restricts the first plate to allow the first plate to move relative to the second plate.

5. The apparatus of claim 4, further comprising an elastic member provided between the first and second plates.

6. The apparatus of claim 3, further comprising:
a plunger inserted into a first surface of the second chamber adjacent to a second surface of the first chamber, the plunger comprising a support body projecting from the first surface of the second chamber.

7. The apparatus of claim 1, wherein the support unit further comprises:
a horizontal moving member that moves the second chamber horizontally relative to the first chamber along one direction, wherein the first surface of the second chamber and the second surface of the first chamber face each other and are inclined in parallel with each other along the one direction.

8. The apparatus of claim 7, further comprising:
a plunger inserted into the first surface of the second chamber adjacent to the second surface of the first chamber, the plunger comprising a support body aligning a position of the second chamber moving toward the first chamber, the support body projecting from the first surface of the second chamber.

9. The apparatus of claim 7, wherein the support unit further comprises a rotation member to make the first surface of the second chamber face upward by rotating the second chamber.

10. The apparatus of claim 1, wherein the support unit comprises a support shaft having a first end connected to the second chamber to support the second chamber.

11. The apparatus of claim 10, wherein the support unit further comprises:
a first plate connected to a second end of the support shaft;
a second plate provided adjacent the first plate; and
an elastic member provided between the first and second plates.

12. The apparatus of claim 10, further comprising:
a sealing member provided in the gap between the first and second chambers to close the gap during the vacuum state.

13. The apparatus of claim 10, further comprising:
a plunger inserted into a first surface of the second chamber adjacent to a second surface of the first chamber, the plunger comprising a support body projecting from the first surface of the second chamber to support the second chamber.

14. The apparatus of claim 10, wherein the support unit further comprises a horizontal moving member that moves the second chamber horizontally relative to the first chamber along one direction,
wherein the first surface of the second chamber and the second surface of the first chamber face each other and are inclined in parallel with each other along the one direction.

15. The apparatus of claim 14, further comprising:
a plunger inserted into the first surface of the second chamber adjacent to the second surface of the first chamber, the plunger comprising a support body aligning a position of the second chamber moving toward the first chamber and projecting from the first surface of the second chamber.

16. The apparatus of claim 14, further comprising a rotation member to make the first surface of the second chamber face upward by rotating the second chamber.

17. A method of opening/closing a process space in a substrate processing apparatus having first and second chambers, comprising:
providing the second chamber over the first chamber to form a gap therebetween; and
closing a process space after the process space formed inside the first and second chambers is kept in a vacuum state.

18. The method of claim 17, wherein the process space is closed during the vacuum state using a sealing member that is provided in the gap between the first and second chambers.

19. The method of claim 17, wherein the process space is opened by venting the vacuum.
